(19) United States
(12) Patent Application Publication
(10) Pub. No.: US 2025/0087519 A1
(43) Pub. Date: Mar. 13, 2025

(54) BACK GRINDING TAPE HAVING TABS TO ASSIST IN REMOVING THE BACK GRINDING TAPE FROM A WAFER

(71) Applicant: Western Digital Technologies, Inc., San Jose, CA (US)

(72) Inventors: Seng Yu Tan, Perai (MY); Nur Syazwani Mohd Najman, Nibong Tebal (MY); Syith Mohammad, Perai (MY)

(21) Appl. No.: 18/464,779

(22) Filed: Sep. 11, 2023

(51) Int. Cl. H01L 21/683; H01L 21/304; H01L 21/67

(52) U.S. Cl. CPC H01L 21/6836; H01L 21/304; H01L 21/67132; H01L 2221/68327

(57) ABSTRACT

A back grinding tape (BG) has one or more tabs extending from a center region. The center region is adhered to a wafer during a wafer back grinding step of a semiconductor die fabrication process. When the wafer back grinding step is complete, a sensor directs a gripping mechanism to a particular tab. When the gripping mechanisms has grabbed a gripping region defined by the tab, a table on which the wafer is placed moves in a particular direction. Movement of the table, in combination with the gripping mechanism holding the gripping region, causes the BG tape to be removed from the wafer.

### BACKGROUND

During a semiconductor die fabrication process, a back grinding step is used to thin a wafer to a desired thickness. For example, during the back grinding step, a grinding wheel removes wafer material from a back side of the wafer until the desired thickness is reached. A back grinding (BG) tape is typically adhered to a top surface of the wafer on which various components have been fabricated. The BG tape protects the components on the top surface of the wafer as the top surface of the wafer is typically facing down during the back grinding step.

After the back grinding step is complete, the BG tape is removed from the wafer. To remove the BG tape, a sensor is used to detect the edge of the wafer and a de-taping tape, typically a piece of heat tape, is applied to the BG tape. Heat is then applied to the de-taping tape which causes the de-taping tape to bond with the BG tape. The de-taping tape is then cut and a gripping mechanism grabs the end of the de-taping tape. A table on which the wafer has been placed during the back grinding step moves in a particular direction which causes the de-taping tape to pull the BG tape from the wafer.

However, there may be times when the de-taping tape is improperly attached to the BG tape. As a result, when the BG tape is removed from the wafer, the improper attachment of the de-taping tape may cause portions of the wafer to crack.

Accordingly, it would be beneficial eliminate the use of de-taping tape when removing BG tape from a wafer.

### SUMMARY

The present application describes back grinding (BG) tape that includes one or more tabs extending from an outer perimeter. For example, the BG tape includes a center region that is shaped and sized to overlay a wafer. The one or more tabs extend from a perimeter of the center region and define a gripping region that can be used as a starting point from which the BG tape is removed from the wafer.

Accordingly, examples of the present disclosure describe a support tape for a wafer. In an example, the support tape includes a center region having a first surface and a second surface opposite the first surface. An adhesive layer is provided on at least one of the first surface and the second surface and is used to secure the center region to the wafer. A tab is formed from the support tape and extends from an outer edge of the center region. In an example, the tab defines a gripping region for removal of the center region from the wafer.

Examples of the present disclosure also describe a method that includes adhering support tape to a wafer. In an example, the support tape includes a first portion and a second portion. The first portion may cover a surface of the wafer and the second portion may extend beyond an edge of the surface of the wafer. Upon completion of a wafer back grinding process, the second portion is used to begin removing the support tape from the surface of the wafer.

In another example, the present disclosure describes a back grinding support means for a wafer. In an example, the back grinding support means includes a center region having a coupling means on a surface. The coupling means may be used to secure the back grinding support means to the wafer. The back grinding support means may also include a gripping means. In an example, the gripping means extends from a perimeter of the center region and defines a gripping region. The gripping means and the center region form a single, unitary piece. The gripping region may be used to remove the back grinding support means from the wafer.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 illustrates back grinding tape having a number of tabs according to an example.

FIG. 2 illustrates the back grinding tape of FIG. 1 being adhered to a wafer according to an example.

FIG. 3 illustrates how one of the tabs of the back grinding tape of FIG. 1 may be used as a starting point to remove the back grinding tape from the wafer of FIG. 2 according to an example.

FIG. 4 illustrates a method for removing back grinding tape from a wafer according to an example.

FIG. 5 is a system diagram of a computing device according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Back grinding (BG) tape is typically attached to a surface of a wafer during a wafer back grinding step of a semiconductor die fabrication process. The BG tape protects various components that have been fabricated on the surface of the wafer. When the back grinding step is complete, the BG tape is removed from the wafer.

Current solutions for removing BG tape from the wafer include multiple steps. For example, when the back grinding step is complete, a sensor detects the edge of the wafer. De-taping tape (e.g., a heat tape) is then applied to the BG tape. A location at which the de-taping tape is placed is based on the detected edge.

A heater is then placed on the de-taping tape. Heat from the heater melts the de-taping tape and causes the de-taping tape to adhere to the BG tape. A cutting mechanism cuts the de-taping tape which forms an end, or a gripping surface, on the de-taping tape. A gripping mechanism may then be used to sense and/or grip the end/gripping surface of the de-taping tape. A table (e.g., a chuck table) on which the wafer is place is then moved in a particular direction. As the table is moved in the particular direction, the gripping mechanism, in combination with the de-taping tape, peels or otherwise removes the BG tape from the wafer.

The BG tape removal process described above involves multiple steps and typically requires multiple sensors. For example, a first sensor may be required to detect the edge of the wafer, a second sensor may be needed to detect a location of the de-taping tape on the wafer and a third sensor may be needed to detect the gripping surface of the de-taping tape. All of the sensors must act flawlessly to avoid any damage to the wafer. Additionally, there may be situations in which the de-taping tape is improperly attached to the BG tape. As a result, when the BG tape is removed from the wafer, the improper attachment of the de-taping tape may cause portions of the wafer to crack.

To address the above, the present application describes back grinding (BG) tape for a wafer. The BG tape includes a center region and one or more tabs that extend from a perimeter of the center region. The center region and the one or more tabs form a single, unitary piece. In an example, the center region is shaped and sized to overlay a wafer. The one or more tabs define a gripping region that can be used as a starting point from which the BG tape is removed from the wafer.

Because the tabs and center region form a single, unitary piece, the process of removing BG tape from the wafer is greatly simplified when compared with current solutions. Additionally, a single sensor may be used to detect the tab. As such, the risk that de-taping tape will be inaccurately applied to the BG tape is eliminated, thereby reducing the risk that the wafer may crack as the BG tape is removed.

Accordingly, many technical benefits may be realized including, but not limited to, substantially reducing or eliminating the risk of wafer cracking when BG tape is removed from a wafer and reducing the number of steps required for removing BG tape from the wafer.

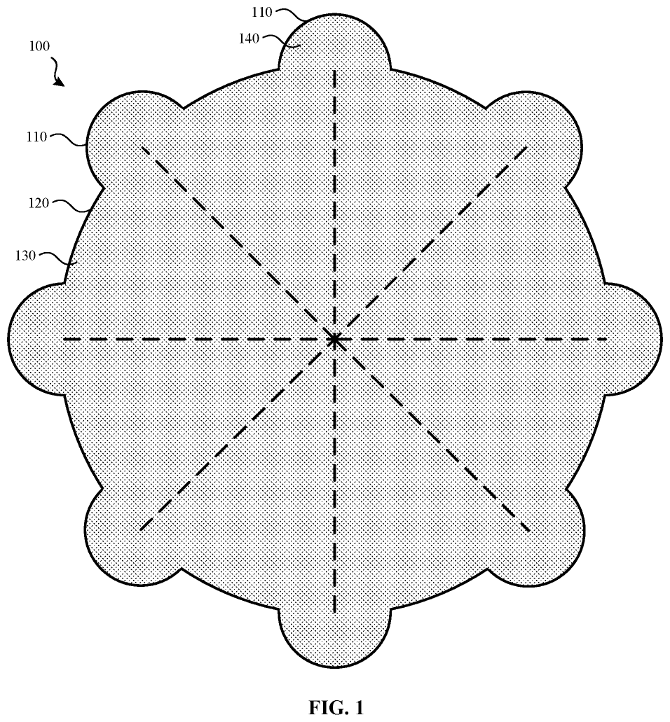

These and other examples will be shown and described in greater detail with respect to FIG. 1-FIG. 5.

FIG. 1 illustrates back grinding (BG) tape 100 having a number of tabs 110 according to an example. In an example, the BG tape 100 includes a center region 120. The center region 120 is shaped and/or sized based, at least in part, on the shape and/or size of a wafer on which the BG tape 100 will be adhered.

The BG tape 100 also includes one or more tabs 110. Each of the one or more tabs 110 extend from a perimeter/outer edge of the center region 120. In an example, each tab 110 has a semicircle shape. When the tab 110 has a semicircle shape, the tab 110 may have a radius between ten millimeters (mm) and thirty mm (which may be adjusted based on need and/or a peeling contact requirement). Although a semicircle shape and an associated radius is specifically mentioned, the tab 110 may have any shape and/or associated measurements.

In an example, the size and/or the shape of each tab 110 may be dependent on, or otherwise be based on, a size and/or shape of the center region 120. In another example, the size and/or shape of each tab 110 may be dependent on a structure (e.g., a crystalline structure) of a wafer on which the BG tape 100 is adhered.

The BG tape 100 may include a top surface and a bottom surface. At least one of the top surface or the bottom surface may include an adhesive layer 130 (represented by the shading). The adhesive layer 130 may be used to secure the BG tape 100 to a wafer.

In the example shown in FIG. 1, the BG tape 100 includes eight different tabs 110. For example, a tab 110 is located every forty-five degrees (represented by the dashed lines) around the center region 120 of the BG tape 100. Although eight tabs are shown and described, and although the tabs 110 are positioned every forty-five degrees around the perimeter of the center region 120, the BG tape 100 may include any number of tabs 110 positioned at various locations.

In an example, each tab 110 and the center region 120 form a single, unitary piece. For example, when the BG tape 100 is cut, sized or otherwise made, the tabs 110 are formed around the perimeter of the center region 120.

Each tab 110 defines a gripping region 140. As will be explained in greater detail herein, the gripping region 140 may be used by a gripping mechanism as a starting point from which the BG tape 100 is removed from a wafer. Because a tab 110 is located every forty-five degrees, or every forty-five degree angle, the gripping mechanism may begin removing the BG tape 100 from the wafer at a variety of different starting points, and each starting point may be associated with a particular pulling angle.

In an example, the pulling angle may be based, at least in part, on a crystalline structure associated with a wafer on which the BG tape 100 is adhered. For example, one wafer may have a crystalline structure (or other properties) that may cause the wafer to crack or break if the BG tape 100 is removed from the wafer at a first pulling angle, but not a second pulling angle. As such, the gripping mechanism may be instructed to remove the BG tape 100 from the wafer at a particular pulling angle that is associated with, or otherwise defined by, a particular tab 110.

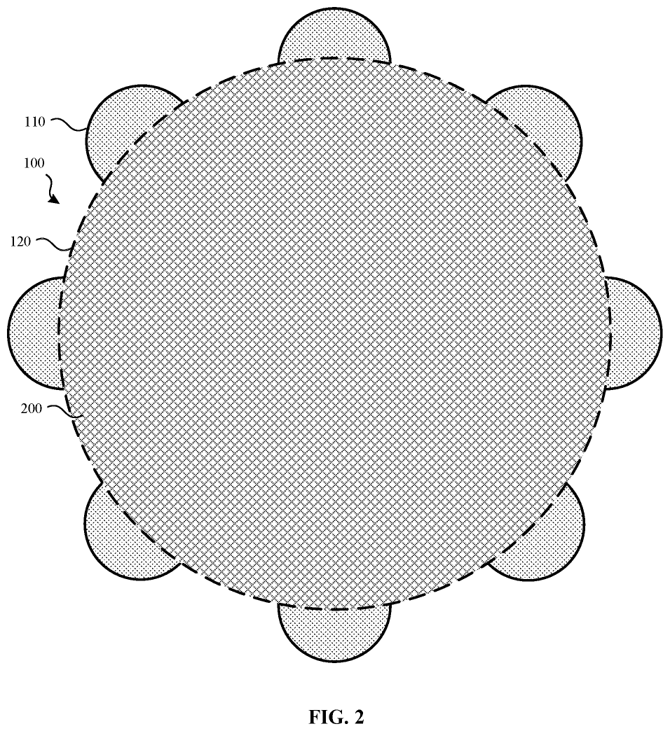

FIG. 2 illustrates the BG tape 100 of FIG. 1 being adhered to a wafer 200 according to an example. In this example, the center region 120 of the BG tape 100 is adhered to the wafer 200 while each tab 110 extends beyond an outer edge of the wafer 200.

As also shown in FIG. 2, when the BG tape 100 has been adhered to the wafer 200, the center region 120 of the BG tape 100 may have a different visual appearance when compared with the tabs 110. The difference in visual appearance may enable a sensor (e.g., a visual sensor/scanner) associated with a gripping mechanism to detect a particular tab 110 and/or distinguish the tab 110 from the center region 120. In another example, each tab 110 may include an indicator (e.g., a visual indicator or other marking/code) that enables a sensor to detect the tab 110 and/or a pulling angle associated with the tab 110.

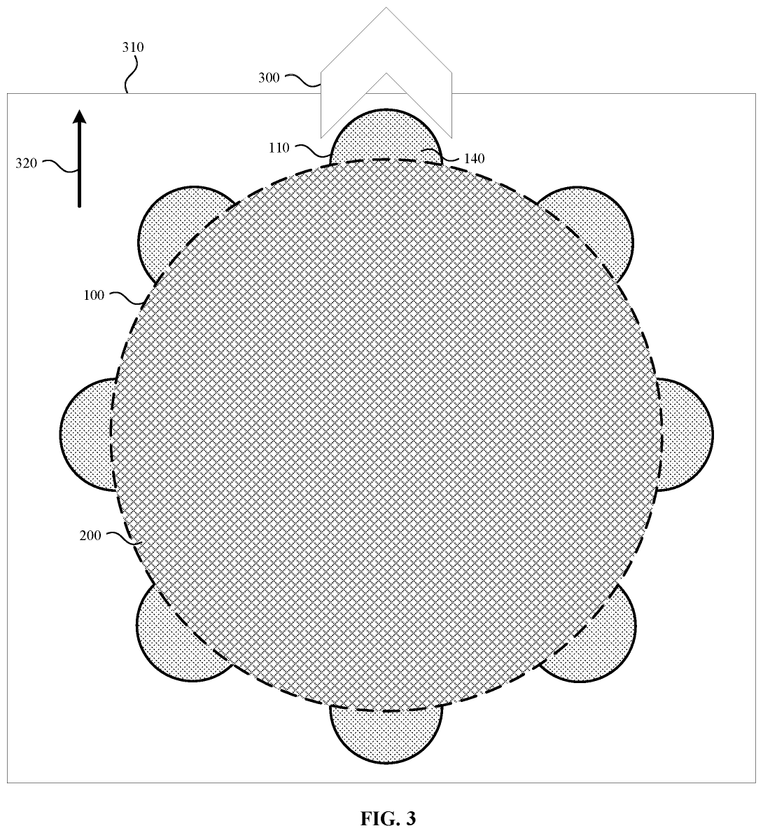

FIG. 3 illustrates how one tab 110 of the BG tape 100 of FIG. 1 may be used as a starting point to remove the BG tape 100 from the wafer 200 of FIG. 2 according to an example. In this example, the wafer 200 and the BG tape 100 have been placed on a table 310 (e.g., a chuck table) as part of a wafer back grinding step. When the back grinding step is complete, a sensor (e.g., a visual sensor) may detect a location of at least one of the tabs 110 and direct a gripping mechanism 300 to the tab 110.

The gripping mechanism 300 may then grab or grip the gripping region 140 defined by the tab 110. The table 310 may then be moved in a particular direction (e.g., in the direction of arrow 320) which causes the BG tape 100 to be removed from the wafer 200.

In an example, the table 310 and/or the wafer 200 may be rotated to help ensure the gripping mechanism 300 grabs a particular tab 110. For example and as previously described, each tab 110 may be associated with a particular pulling angle (e.g., an angle at which the BG tape 100 should be removed from the wafer 200). The pulling angle may be based, at least in part, on a structure (e.g., a crystalline structure) of the wafer 200.

For example, the wafer 200 may be more susceptible to damage if the BG tape 100 is pulled from one pulling angle versus another pulling angle. As such, the gripping mechanism 300, the table 310 and/or the wafer 200 may be positioned/rotated to help ensure a desired tab 110 is grabbed by the gripping mechanism 300. In an example, the desired tab 110 is based, at least in part, on a recipe associated with a semiconductor die fabrication process.

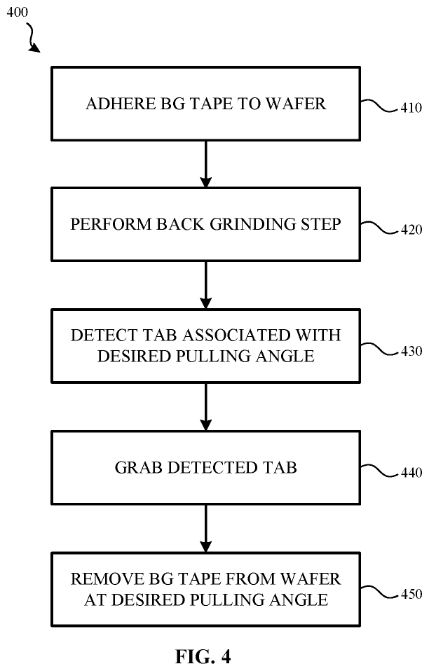

FIG. 4 illustrates a method 400 for removing BG tape from a wafer according to an example. In an example, the method 400 may be used to remove the BG tape 100 from the wafer 200 shown and described with respect to FIG. 2. Additionally, the method 400 may be performed by a machine or device that is configured to remove BG tape from a wafer as part of a semiconductor die fabrication process.

In an example, the method 400 begins when BG tape is adhered (410) to a wafer. In an example, the BG tape is adhered to the wafer prior to an occurrence of a back grinding step of a semiconductor die fabrication process. In an example, the BG tape that is adhered to the wafer includes one or more tabs that extend from a center region of the BG tape. As such, the center region and the tabs form a single, unitary piece of BG tape.

In one example, a sheet of BG tape may be adhered to the wafer and the center region and the tabs may be cut from, or otherwise formed from, the sheet of BG tape. In another example, the center region and the tabs may be pre-cut or pre-formed in the BG tape (e.g., the center region and the tabs may be formed in the BG tape prior to the BG tape being adhered to the wafer).

When the BG tape has been adhered to the wafer, the wafer and the BG tape may be placed on a table (e.g., a chuck table). A back grinding step may then be performed (420) on the wafer.

Upon completion of the back grinding step, a sensor may be used to detect (430) a tab of the BG tape. In an example, the sensor is a vision sensor that may detect a visual difference between the tabs and the center portion of the BG tape. Further, each tab may be associated with a particular pulling angle. As such, the sensor may detect or determine (e.g., based on a semiconductor die fabrication recipe and/or on a structure of the wafer) which tab is associated with a desired pulling angle.

A gripping mechanism may then grab (440) a grabbing region of the detected tab. The table on which the wafer is place may then move in a particular direction which removes (450) the BG tape from the wafer. Because a particular tab is grabbed by the gripping mechanism, the BG tape is removed from the wafer at a desired pulling angle.

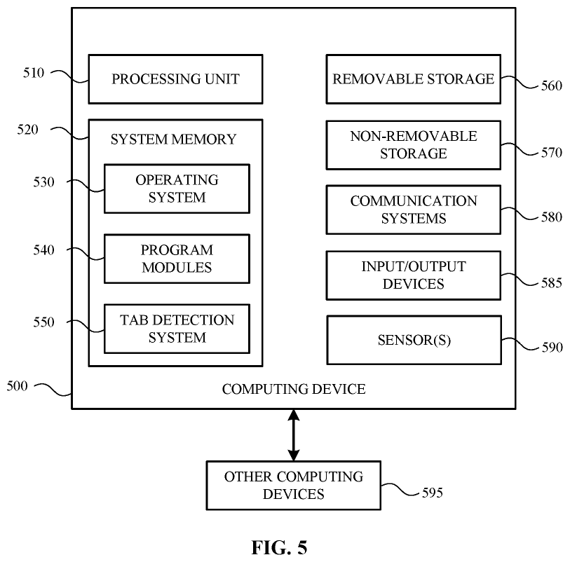

FIG. 5 is a system diagram of a computing device 500 according to an example. The computing device 500, or various components and systems of the computing device 500, may be integrated or associated with a machine or device that is used as part of a semiconductor die fabrication process and/or the various steps (e.g., a back grinding step) of the semiconductor die fabrication process. For example, the computing device 500, or various components or systems of the computing device 500 may be used to detect tabs of BG tape that has been adhered to a wafer. As shown in FIG. 5, the physical components (e.g., hardware) of the computing device are illustrated and these physical components may be used to practice the various aspects of the present disclosure. In addition to the various components shown in FIG. 5, the computing device 500 may also include, or otherwise be associated with the gripping mechanism 300 and/or the table 310 shown and described with respect to FIG. 3.

The computing device 500 may include at least one processing unit 510 and a system memory 520. The system memory 520 may include, but is not limited to, volatile storage (e.g., random access memory), non-volatile storage (e.g., read-only memory), flash memory, or any combination of such memories. The system memory 520 may also include an operating system 530 that controls the operation of the computing device 500 and one or more program modules 540. The program modules 540 may be responsible for executing one or more steps of a semiconductor die fabrication process (e.g., a back grinding step and/or a BG tape removal process). While being executed by the processing unit 510, the program modules 540 may perform the various processes described above.

The computing device 500 may also have additional features or functionality. For example, the computing device 500 may include additional data storage devices (e.g., removable and/or non-removable storage devices) such as, for example, magnetic disks, optical disks, or tape. These additional storage devices are labeled as a removable storage 560 and a non-removable storage 570.

Examples of the disclosure may also be practiced in an electrical circuit comprising discrete electronic elements, packaged or integrated electronic chips containing logic gates, a circuit utilizing a microprocessor, or on a single chip containing electronic elements or microprocessors. For example, examples of the disclosure may be practiced via a system-on-a-chip (SOC) where each or many of the components illustrated in FIG. 5 may be integrated onto a single integrated circuit. Such a SOC device may include one or more processing units, graphics units, communications units, system virtualization units and various application functionality all of which are integrated (or “burned”) onto the chip substrate as a single integrated circuit.

When operating via a SOC, the functionality, described herein, may be operated via application-specific logic integrated with other components of the computing device 500 on the single integrated circuit (chip). The disclosure may also be practiced using other technologies capable of performing logical operations such as, for example, AND, OR, and NOT, including but not limited to mechanical, optical, fluidic, and quantum technologies.

The computing device 500 may include one or more communication systems 580 that enable the computing device 500 to communicate with other computing devices 595 or systems. Examples of communication systems 580 include, but are not limited to, wireless communications, wired communications, cellular communications, radio frequency (RF) transmitter, receiver, and/or transceiver circuitry, a Controller Area Network (CAN) bus, a universal serial bus (USB), parallel, serial ports, etc.

The computing device 500 may also have one or more input devices and/or one or more output devices shown as input/output devices 585. These input/output devices 585 may include a keyboard, a sound or voice input device, haptic devices, a touch, force and/or swipe input device, a display, speakers, etc. The aforementioned devices are examples and others may be used.

The computing device 500 may also include one or more sensors 590. The sensors may be image sensors that are used to detect an edge of a wafer and/or the present of a tab that extends from BG tape that has been adhered to the wafer.

The term computer-readable media as used herein may include computer storage media. Computer storage media may include volatile and nonvolatile, removable and non-removable media implemented in any method or technology for storage of information, such as computer readable instructions, data structures, or program modules.

The system memory 520, the removable storage 560, and the non-removable storage 570 are all computer storage media examples (e.g., memory storage). Computer storage media may include RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other article of manufacture which can be used to store information and which can be accessed by the computing device 500. Any such computer storage media may be part of the computing device 500. Computer storage media does not include a carrier wave or other propagated or modulated data signal.

Examples of the present disclosure describe support tape for a wafer, comprising: a center region having a first surface and a second surface opposite the first surface; an adhesive layer provided on at least one of the first surface and the second surface, the adhesive layer securing the center region to the wafer; and a tab formed from the support tape and extending from an outer edge of the center region, the tab defining a gripping region for removal of the center region from the wafer. In an example, the tab is a first tab and wherein the support tape further comprises a second tab, the second tab formed from the support tape and extending from the outer edge of the center region. In an example, the second tab is positioned on the outer edge of the center region at a forty-five degree angle from the first tab. In an example, the tab has a semicircle shape. In an example, the semicircle shape has a radius between ten millimeters (mm) and thirty mm. In an example, the tab is associated with a pulling angle, the pulling angle specifying an angle at which the support tape is removed from the wafer. In an example, the pulling angle is based, at least in part, on a structure of the wafer.

Examples also describe a method, comprising: adhering support tape to a wafer, the support tape comprising a first portion and a second portion, the first portion covering a surface of the wafer and the second portion extending beyond an edge of the surface of the wafer; and upon completion of a wafer back grinding process, using the second portion to begin removing the support tape from the surface of the wafer. In an example, the second portion is a tab that extends from the first portion. In an example, the method also includes sensing a location of the second portion. In an example, the support tape further comprises a third portion extending beyond the edge of the surface of the wafer. In an example, the third portion is positioned at a forty-five degree angle from the second portion. In an example, the second portion is associated with a first pulling angle and the third portion is associated with a second pulling angle. In an example, the second portion is used to begin removing the support tape based, at least in part, on the first pulling angle. In an example, the second portion is used to begin removing the support tape based, at least in part, on a structure of the wafer.

Examples also describe a back grinding support means for a wafer, comprising: a center region having a coupling means on a surface, the coupling means for securing the back grinding support means to the wafer; and a gripping means extending from a perimeter of the center region, the gripping means defining a gripping region for removing the back grinding support means from the wafer, the gripping means and the center region forming a single, unitary piece. In an example, the gripping means is a first gripping means and wherein the grinding support means further comprises a second gripping means extending from the perimeter of the center region. In an example, the second gripping means is positioned on the perimeter at least at a forty-five degree angle from the first gripping means. In an example, the first gripping means and the second gripping means are associated with different pulling angles. In an example, the gripping means is formed during a back grinding support means cutting process.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. Support tape for a wafer, comprising:
a center region having a first surface and a second surface opposite the first surface;
an adhesive layer provided on at least one of the first surface and the second surface, the adhesive layer securing the center region to the wafer; and
a tab formed from the support tape and extending from an outer edge of the center region, the tab defining a gripping region for removal of the center region from the wafer.

2. The support tape of claim 1, wherein the tab is a first tab and wherein the support tape further comprises a second tab, the second tab formed from the support tape and extending from the outer edge of the center region.

3. The support tape of claim 2, wherein the second tab is positioned on the outer edge of the center region at a forty-five degree angle from the first tab.

4. The support tape of claim 1, wherein the tab has a semicircle shape.

5. The support tape of claim 4, wherein the semicircle shape has a radius between ten millimeters (mm) and thirty mm.

6. The support tape of claim 1, wherein the tab is associated with a pulling angle, the pulling angle specifying an angle at which the support tape is removed from the wafer.

7. The support tape of claim 6, wherein the pulling angle is based, at least in part, on a structure of the wafer.

8. A method, comprising:
adhering support tape to a wafer, the support tape comprising a first portion and a second portion, the first portion covering a surface of the wafer and the second portion extending beyond an edge of the surface of the wafer; and
upon completion of a wafer back grinding process, using the second portion to begin removing the support tape from the surface of the wafer.

9. The method of claim 8, wherein the second portion is a tab that extends from the first portion.

10. The method of claim 8, further comprising sensing a location of the second portion.

11. The method of claim 8, wherein the support tape further comprises a third portion extending beyond the edge of the surface of the wafer.

12. The method of claim 11, wherein the third portion is positioned at a forty-five degree angle from the second portion.

13. The method of claim 11, wherein the second portion is associated with a first pulling angle and the third portion is associated with a second pulling angle.

14. The method of claim 13, wherein the second portion is used to begin removing the support tape based, at least in part, on the first pulling angle.

15. The method of claim 13, wherein the second portion is used to begin removing the support tape based, at least in part, on a structure of the wafer.

16. A back grinding support means for a wafer, comprising:
a center region having a coupling means on a surface, the coupling means for securing the back grinding support means to the wafer; and
a gripping means extending from a perimeter of the center region, the gripping means defining a gripping region for removing the back grinding support means from the wafer, the gripping means and the center region forming a single, unitary piece.

17. The back grinding support means of claim 16, wherein the gripping means is a first gripping means and wherein the grinding support means further comprises a second gripping means extending from the perimeter of the center region.

18. The back grinding support means of claim 17, wherein the second gripping means is positioned on the perimeter at least at a forty-five degree angle from the first gripping means.

19. The back grinding support means of claim 17, wherein the first gripping means and the second gripping means are associated with different pulling angles.

20. The back grinding support means of claim 16, wherein the gripping means is formed during a back grinding support means cutting process.
